(19) United States
(12) Patent Application Publication
(10) Pub. No.: US 2026/0020429 A1
(43) Pub. Date: Jan. 15, 2026

(54) LIGHT-EMITTING ELEMENT, DISPLAY DEVICE, AND METHOD FOR PRODUCING LIGHT-EMITTING ELEMENT

(71) Applicant: Sharp Display Technology Corporation, Kameyama City, Mie (JP)

(72) Inventor: YOSHIHIRO UETA, Sakai City, Osaka (JP)

(21) Appl. No.: 18/994,227

(22) PCT Filed: Aug. 5, 2022
(86) PCT No.: PCT/JP2022/030056

§ 371 Date: Jan. 14, 2025

(51) Int. Cl. H10K 50/115; H10K 71/40

(52) U.S. Cl. CPC H10K 50/115; H10K 71/40

(57) ABSTRACT

A matrix material includes an inorganic semiconductor and an additive, fills a space between a first quantum dot and a second quantum dot, and includes a first portion adjacent to the first quantum dot, a second portion adjacent to the second quantum dot, and a third portion positioned between the first portion and the second portion and having a concentration of the additive higher than those of the first portion and the second portion.

### TECHNICAL FIELD

The disclosure relates to a light-emitting element, a display device, and a method for manufacturing a light-emitting element.

### BACKGROUND ART

PTL 1 discloses a quantum dot in which a fluoride-containing ligand or a fluoride anion is bonded to a surface thereof.

### CITATION LIST

### Patent Literature

PTL 1: JP 2020-180278 A (published on Nov. 5, 2020)

### SUMMARY

### Technical Problem

The disclosure described in PTL 1 is problematic in that a durability of the light-emitting element is low.

### Solution to Problem

A light-emitting element according to an aspect of the disclosure includes a light-emitting layer including a first quantum dot, a second quantum dot, and a matrix material (1) including an inorganic semiconductor and an additive, (2) filling a space between the first quantum dot and the second quantum dot, and (3) including a first portion adjacent to the first quantum dot, a second portion adjacent to the second quantum dot, and a third portion positioned between the first portion and the second portion and having a concentration of the additive higher than those of the first portion and the second portion.

A method for manufacturing a light-emitting element according to an aspect of the disclosure includes applying a dispersion including a precursor of an inorganic semiconductor, an additive, a plurality of quantum dots, and a solvent, and modifying the precursor of the inorganic semiconductor into an inorganic semiconductor, bringing a crystal growth rate of the inorganic semiconductor to equal to or less than a thermal diffusion rate of the additive.

### Advantageous Effects of Disclosure

According to an aspect of the disclosure, it is possible to improve a durability of a light-emitting element.

### BRIEF DESCRIPTION OF DRAWINGS

FIG. 1 is a cross-sectional view illustrating a configuration example of a light-emitting element according to an embodiment of the disclosure.

FIG. 2 is a schematic view illustrating an example of a region between quantum dots illustrated in FIG. 1.

FIG. 3 is a schematic view illustrating another example of the region between the quantum dots illustrated in FIG. 1.

FIG. 4 is a schematic view illustrating a configuration example of a light-emitting layer illustrated in FIG. 1.

FIG. 5 is a schematic view illustrating another configuration example of the light-emitting layer illustrated in FIG. 1.

FIG. 6 is a schematic view focusing on a first quantum dot and a second quantum dot adjacent to each other and illustrated in FIG. 4 and FIG. 5.

FIG. 7 is a view illustrating a concentration distribution example of an additive along an arrow BC in FIG. 5.

FIG. 8 is a schematic view illustrating an example of the additive being scattered in the configuration example illustrated in FIG. 4.

FIG. 9 is a flowchart illustrating an example of a method for manufacturing the light-emitting element illustrated in FIG. 1.

FIG. 10 is a schematic view illustrating an example of a dispersion used in a process of forming the light-emitting layer illustrated in FIG. 9.

FIG. 11 is a flowchart illustrating an example of the process of forming the light-emitting layer illustrated in FIG. 9.

FIG. 12 is a graph showing light-emission characteristics of the light-emitting element of an example according to the disclosure and a light-emitting element according to a comparative example.

FIG. 13 is a schematic view illustrating a configuration example of the light-emitting layer of the light-emitting element according to an embodiment of the disclosure.

FIG. 14 is a schematic view illustrating an example of the additive being scattered in the configuration example illustrated in FIG. 13.

FIG. 15 is a schematic view focusing on the first quantum dot and the second quantum dot adjacent to each other and illustrated in FIG. 13 and FIG. 14.

FIG. 16 is a schematic view illustrating a modified example of the light-emitting layer of the light-emitting element according to an embodiment of the disclosure.

FIG. 17 is a schematic view illustrating a configuration example of a light-emitting device according to an embodiment of the disclosure.

### DESCRIPTION OF EMBODIMENTS

### First Embodiment

### Cross-Sectional Configuration of Light-Emitting Element

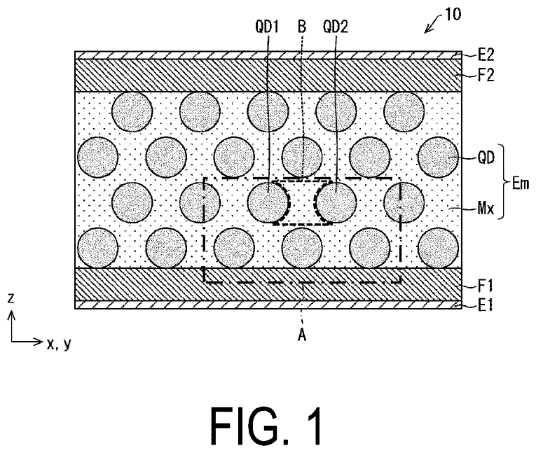

FIG. 1 is a cross-sectional view illustrating a configuration example of a light-emitting element according to an embodiment of the disclosure. As illustrated in FIG. 1, a light-emitting element 10 according to the present embodiment includes a first electrode E1 and a second electrode E2 facing each other, and a light-emitting layer Em positioned between the first electrode E1 and the second electrode E2. The light-emitting element 10 may further include a charge function layer F1 between the first electrode E1 and the light-emitting layer Em, and may further include a charge function layer F2 between the second electrode E2 and the light-emitting layer Em.

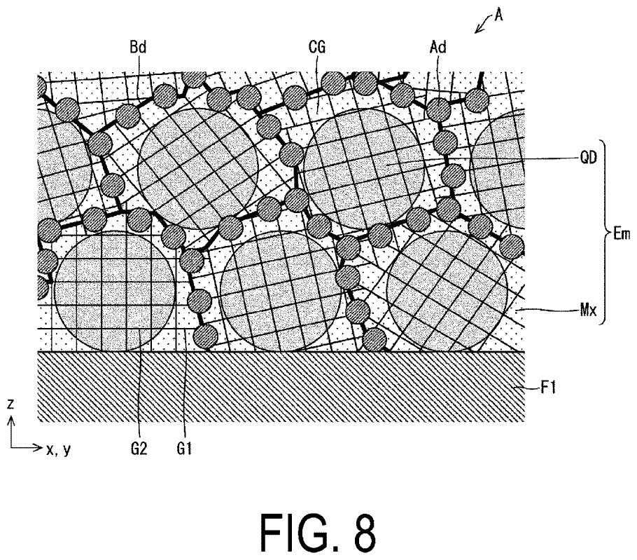

At least one of first electrode E1 or the second electrode E2 is a transparent electrode. One of the first electrode E1 and the second electrode E2 is an anode and the other is a cathode. The charge function layers F1, F2 may include any one or more of a charge injection layer, a charge transport layer, and a charge blocking layer. The light-emitting layer Em includes a plurality of quantum dots QD including a first quantum dot QD1 and a second quantum dot QD2, and a matrix material Mx. The matrix material Mx (1) includes an inorganic semiconductor and an additive Ad (refer to FIG. 8), and (2) fills a space between the first quantum dot QD1 and the second quantum dot QD2. The additive Ad may include at least one of a halogen element or an organic compound.

The matrix material Mx refers to a member including and holding other matter, and can be referred to as a substrate, a base material, or a filler. The matrix material Mx may be solid at room temperature. The matrix material Mx may be a member that includes and holds the first quantum dot QD1 and the second quantum dot QD2. The matrix material Mx may be a constituent element of the light-emitting layer Em including the first quantum dot QD1 and the second quantum dot QD2.

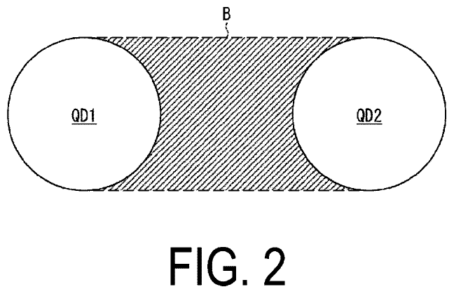

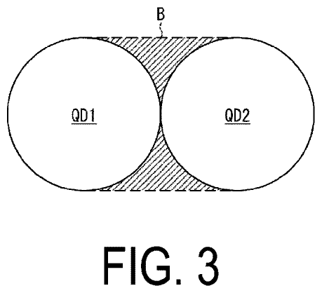

FIG. 2 and FIG. 3 are each a schematic view illustrating an example of a region between the quantum dots illustrated in FIG. 1. The matrix material Mx may be filled in the light-emitting layer Em. As illustrated in FIG. 1, the matrix material Mx may fill a region (space) B between the first and second quantum dots QD1, QD2. As illustrated in FIG. 2 and FIG. 3, the region B is a region surrounded by two straight lines (common outer tangent lines) in contact with outer peripheries of the first and second quantum dots QD1, QD2 and outer peripheries of the first and second quantum dots QD1, QD2 facing each other in a cross-sectional view. As illustrated in FIG. 3, even when the first quantum dot QD1 is close to the second quantum dot QD2, the region B can exist. As illustrated in FIG. 1, the matrix material Mx may fill a region (space) other than the plurality of quantum dots including the first and second quantum dots QD1, QD2 in the light-emitting layer Em. The matrix material Mx may fill a region (space) other than quantum dot groups in the light-emitting layer Em. Note that three or more quantum dots including the first and second quantum dots QD1, QD2 are collectively referred to as a quantum dot group.

The matrix material Mx may fill the region (space) other than the plurality of quantum dots including the first and second quantum dots QD1, QD2 in the light-emitting layer Em. Outer edges (upper surface and lower surface) of the light-emitting layer Em may be covered with the matrix material Mx. Alternatively, a portion of the matrix material Mx may be configured to extend from the outer edges of the light-emitting layer Em, positioning the quantum dots QD away from the outer edges. The outer edges of the light-emitting layer Em need not be formed only by the matrix material Mx, and part of the quantum dots may be exposed from the matrix material Mx. The matrix material Mx may indicate a portion of the light-emitting layer Em excluding the plurality of quantum dots including the first and second quantum dots QD1, QD2.

The matrix material Mx may enclose the first and second quantum dots QD1, QD2. The matrix material Mx may enclose a quantum dot group including the first and second quantum dots QD1, QD2. The matrix material Mx may be formed filling space formed between the first and second quantum dots QD1, QD2. The matrix material Mx may partially or completely fill space between the quantum dot groups including the first and second quantum dots QD1, QD2. The light-emitting layer Em includes the quantum dot groups including the first and second quantum dots QD1, QD2, and the matrix material Mx fills a region other than the quantum dot groups. The first and second quantum dots QD1, QD2 may be embedded in the matrix material Mx at intervals.

The matrix material Mx may include a continuous film having an area equal to or greater than 1000 nm² in a plane direction orthogonal to a layer thickness direction of the light-emitting layer Em. The continuous film means a film not partitioned by a material other than a material constituting the continuous film in one plane. The continuous film may be in the form of an integrated film that is continuous without interruption by chemical bonding of the material constituting the matrix material Mx.

The matrix material Mx may be the same material as that of a shell of the first quantum dot QD1. In this case, an average distance between adjacent cores (core-to-core distance) may be equal to or greater than 3 nm or may be equal to or greater than 5 nm. Alternatively, the average distance between adjacent cores may be 0.5 times or more an average core diameter. The core-to-core distance is obtained by averaging the shortest distances between 20 adjacent cores. The core-to-core distance may be kept wider than the distance when the shells are in contact with each other. The average core diameter is obtained by averaging the core diameters of 20 adjacent cores in a cross-sectional observation. The core diameter can be a diameter of a circle having the same area as the core area in the cross-sectional observation.

A concentration of the matrix material Mx in the light-emitting layer Em is, for example, an area ratio occupied by the matrix material Mx in a cross section of the light-emitting layer Em. This concentration may be from 10% to 90%, or may be from 30% to 70% in a cross-sectional observation. This concentration may be measured, for example, from an area ratio in image processing in a cross-sectional observation. When the first quantum dot QD1 has a core/shell structure, a concentration of the shell may be from 1% to 50%. When the shell material and the matrix material Mx are the same (same composition) and the shell and the matrix material Mx are indistinguishable, the concentration of the region including the matrix material Mx and the shell may be in a numerical range obtained by adding a numerical range of the concentration of the shell to a numerical range of the concentration of the matrix material Mx. A ratio of the core and the shell of the quantum dot QD and the matrix material Mx may be adjusted, bringing the total to 100% or less as appropriate. Thus, when the shell and the matrix material Mx are indistinguishable, the shell may be part of the matrix material Mx. The light-emitting layer Em may be constituted by a plurality of the quantum dots including the first and second quantum dots QD1, QD2, and the matrix material Mx. An intensity of the carbon detected by the chain structure when the light-emitting layer Em is analyzed may be equal to or less than a noise level.

The constituent material of the matrix material Mx desirably has a wider band gap than those of the constituent materials of the first and second quantum dots QD1, QD2. As a material constituting the matrix material Mx, a semiconductor or an insulator can be used. Examples of the constituent material of the matrix material Mx include a metal sulfide and/or a metal oxide. The metal sulfide may be, for example, zinc sulfide (ZnS), zinc magnesium sulfide (ZnMgS, ZnMgS₂), gallium sulfide (GaS, Ga₂S₃), zinc tellurium sulfide (ZnTeS), magnesium sulfide (MgS), zinc gallium sulfide (ZnGa₂S₄), and magnesium sulfide (MgGa₂S₄). The metal oxide may be zinc oxide (ZnO), titanium oxide (TiO₂), tin oxide (SnO₂), tungsten oxide (WO₃), and zirconium oxide (ZrO₂). Note that a chemical formula written within parentheses after a compound name is a representative example. In addition, the composition ratio described in the chemical formula is desirably stoichiometric in which the actual composition of the compound is the same as the chemical formula but is not necessarily stoichiometric.

The structure of the matrix material Mx described above need not be observed over the entirety of the light-emitting layer Em as long as the structure described above is understood by observing the light-emitting layer Em across a width of about 100 nm in a cross-sectional observation. The matrix material Mx may include a substance different from the main material (for example, an inorganic substance such as an inorganic semiconductor) such as, for example, an additive.

### Configuration of Light-Emitting Layer

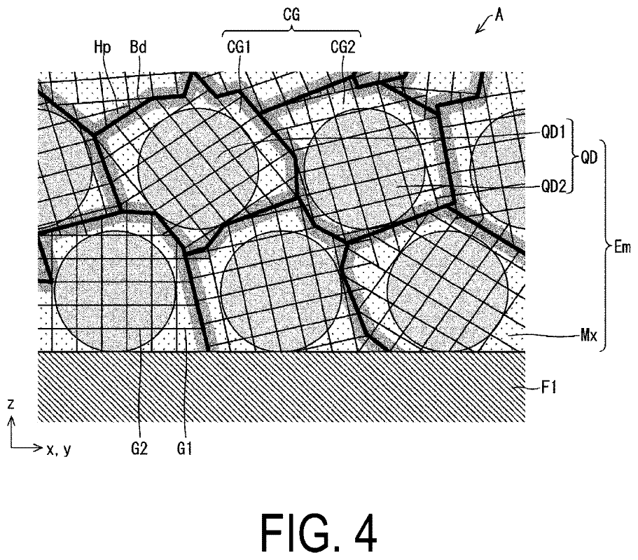

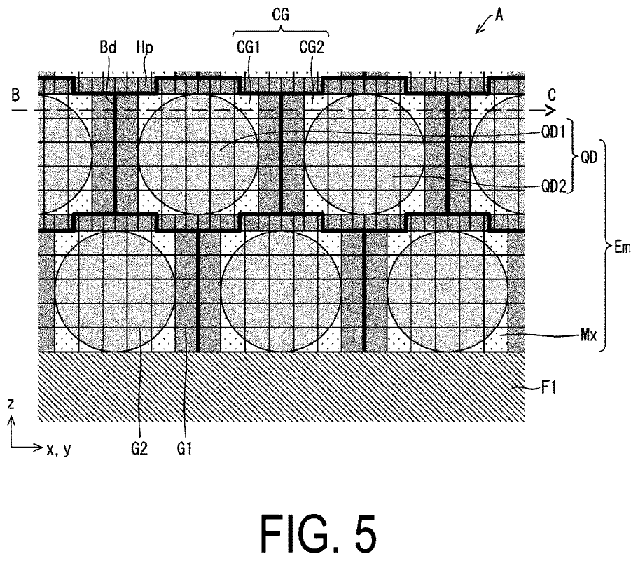

FIG. 4 and FIG. 5 are each a schematic view illustrating a configuration example of the light-emitting layer illustrated in FIG. 1, and correspond to enlarged cross-sectional views obtained by enlarging a portion indicated by a circle A in FIG. 1. As illustrated in FIG. 4 and FIG. 5, the matrix material Mx includes a plurality of crystal portions CG including a first crystal portion CG1 and a second crystal portion CG2. The matrix material Mx may be a so-called “polycrystalline body.” The first crystal portion CG1 is a single crystal epitaxially grown from the surface of the first quantum dot QD1, and the second crystal portion CG2 is a single crystal epitaxially grown from the surface of the second quantum dots QD2. An arrangement and an orientation of a crystal lattice G1 of the first crystal portion CG1 follow an arrangement and an orientation of a crystal lattice G2 of the first quantum dot QD1. An arrangement and an orientation of a crystal lattice G1 of the second crystal portion CG2 follow an arrangement and an orientation of a crystal lattice G2 of the second quantum dot QD2. Note that a plurality of the crystal portions CG may be in contact with one quantum dot QD, or one crystal portion CG may enclose two or more quantum dots QD. Hereinafter, to simplify the description, a configuration example in which the first crystal portion CGI encloses the first quantum dot QD1 as illustrated in FIG. 4 and FIG. 5 will be described unless otherwise specified.

As illustrated in FIG. 4 and FIG. 5, between the first quantum dot QD1 and the second quantum dot QD2 adjacent to each other, the first crystal portion CGI grown from the surface of the first quantum dot QD1 and the second crystal portion CG2 grown from the surface of the second quantum dot QD2 are in contact with each other and form a crystal grain boundary Bd. As illustrated in FIG. 4, the arrangement of the quantum dots QD is typically random, and crystal orientations of outermost layers of the quantum dots QD differ from each other. Therefore, at the crystal grain boundary Bd, the crystal lattices G1 and the crystal orientations of the first crystal portion CGI and the second crystal portion CG2 are incommensurate. Further, as illustrated in FIG. 5, even if the quantum dots QD are aligned and the crystal orientations of the outermost layers of the quantum dots QD are commensurate, the crystal lattices G1 of the first crystal portion CG1 and the second crystal portion CG2 are incommensurate as long as the distance between the first quantum dot QD1 and the second quantum dot QD2 is not an integer multiple of the lattice constant of the first crystal portion CG1 and the second crystal portion CG2. With at least one of the crystal orientation or the crystal lattice G1 being incommensurate at the crystal grain boundary Bd of the crystal portions CG, the crystal grain boundary Bd is also called an “incommensurate crystal surface.”

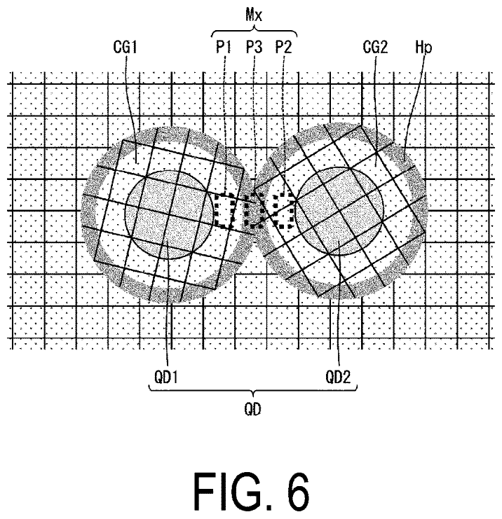

FIG. 6 is a schematic view focusing on the first quantum dot QD1 and the second quantum dot QD2 adjacent to each other and illustrated in FIG. 4. As illustrated in FIG. 6, the matrix material Mx includes a first portion P1 adjacent to the first quantum dot QD1, a second portion P2 adjacent to the second quantum dot QD2, and a third portion P3 positioned between the first portion P1 and the second portion P2. A concentration of an additive Ad (refer to FIG. 8) in the third portion P3 is higher than concentrations of the additive Ad in the first portion P1 and the second portion P2.

In the matrix material Mx, a high concentration distribution region Hp in which the concentration of the additive Ad is higher than those of the first portion P1 and the second portion P2 is formed and includes the third portion P3. The first portion P1 and the second portion P2 can include portions in which the concentration of the additive Ad is 0. The additive Ad is scattered in the third portion P3.

An intermediate position between the first quantum dot QD1 and the second quantum dot QD2 is present in the third portion P3. Each of the first quantum dot QD1 and the second quantum dot QD2 is individually surrounded by the high concentration distribution region Hp. Thus, as illustrated in FIG. 4, the high concentration distribution region Hp has a mesh shape in a cross-sectional view of the light-emitting layer Em in a cross section including the first quantum dot QD1 and the second quantum dot QD2.

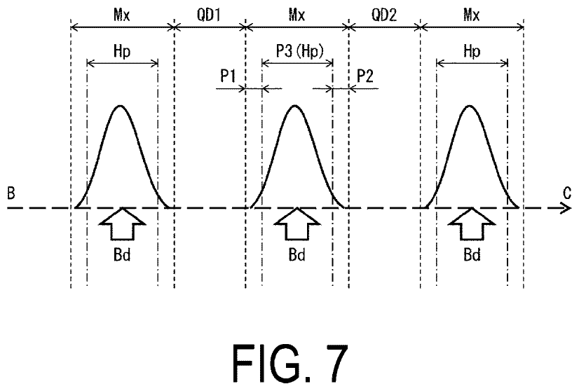

FIG. 7 is a view illustrating a concentration distribution example of the additive along an arrow BC in FIG. 5. As illustrated in FIG. 7, the concentration of the additive Ad (refer to FIG. 8) is highest at the crystal grain boundary Bd and decreases from the crystal grain boundary Bd toward the surfaces of the first quantum dot QD1 and the second quantum dot QD2. Note that, although this concentration distribution has been described with reference to FIG. 5, the same concentration distribution may be present in other configurations (for example, FIG. 4). Note that, in a configuration example in which a plurality of the crystal portions CG are in contact with the first quantum dot QD1, when one three-dimensional region including the plurality of crystal portions CG in contact with the first quantum dot QD1 is assumed, the concentration of the additive Ad decreases from a boundary surface of the three-dimensional region toward the surface of the first quantum dot QD1.

Accordingly, the matrix material Mx includes the plurality of crystal portions CG, and at least part of the crystal grain boundary Bd of the matrix material Mx is included in the high concentration distribution region Hp. The concentration of the additive Ad (refer to FIG. 8) decreases from the boundary surface of the three-dimensional region toward the surfaces of the first quantum dot QD1 and the second quantum dot QD2. The concentration of the additive Ad at a certain position can be calculated as a density of the additive Ad in a unit volume centered at the position.

FIG. 8 is a schematic view illustrating an example of the additive being scattered in the configuration example illustrated in FIG. 4. As illustrated in FIG. 8, the additive Ad is scattered in the crystal grain boundary Bd of the crystal portions CG and the vicinity thereof (that is, in the high concentration distribution region Hp). Thus, the additive Ad inactivates lattice defects in the crystal grain boundary Bd (and the vicinity thereof). In a configuration without the additive Ad, the crystal grain boundary Bd is an incommensurate crystal surface, and therefore dangling bonds are generated at high density in the crystal grain boundary Bd (and the vicinity thereof). A dangling bond becomes a non-light-emission combination center or a carrier trap, and reduces the luminous efficiency of the light-emitting layer Em. On the other hand, in the configuration according to the disclosure, the additive Ad receives unpaired electrons from the dangling bonds. Thus, the dangling bonds are eliminated.

Thus, the additive Ad includes one or more halogen elements. The one or more halogen elements include any one or more of fluorine, chlorine, bromine, and iodine. The one or more halogen elements preferably belong to a period identical to or higher than that of at least one element constituting the matrix material Mx. Further, when the one or more halogen elements include two or more halogen elements, preferably a halogen element having a highest mass ratio among the two or more halogen elements belongs to a period identical to or higher than that of at least one element constituting the matrix material Mx.

For the core of the first quantum dot QD1, various compounds such as a group II-VI compound, a group III-V compound, a perovskite compound, and a chalcopyrite compound are used in accordance with characteristics such as a wavelength of light emitted from the first quantum dot QD1. On the other hand, for the shell of the first quantum dot QD1, to confine excitons in the core of the first quantum dot QD1, a compound having a band gap greater than that of the core material is often used. Constituent materials of the shell of the first quantum dot QD1 may be same as constituent materials of the inorganic semiconductor included in the matrix material Mx. The band gap of the inorganic semiconductor included in the matrix material Mx may be greater than a band gap of the constituent materials of the core of the first quantum dot QD1.

In the disclosure, a group III-V compound refers to an inorganic compound including a group III element and a group V element at a composition ratio of approximately 1 to 1, and a group II-VI compound refers to an inorganic compound including a group II element and a group VI element at a composition ratio of approximately 1 to 1. The group II element includes a group 2 element and a group 12 element. The group III element includes a group 3 element and a group 13 element. The group IV element includes a group 4 element and a group 14 element. The group VI element includes a group 6 element and a group 16 element. Here, notation of the group numbers of elements using Roman numerals is based on the former International Union of Pure and Applied Chemistry (IUPAC) system or the former Chemical Abstracts Service (CAS) system, and notation of the group numbers of elements using Arabic numerals is based on the new IUPAC system.

A group 6 element is also referred to as a chalcogen element. The chalcogen element includes oxygen, sulfur, selenium, and tellurium. Both a group 2 element and a group 12 element are metal elements. Therefore, the group II-VI compound including a group 6 element is also referred to as a metal chalcogenide. The metal chalcogenide exhibits any one of a wurtzite crystal structure, a zincblende crystal structure, or a rocksalt crystal structure. In a metal chalcogenide, a defect in which a chalcogen atom is missing is likely to occur. An ease of the bonding of the halogen atom to this defect depends on the ionic radius regardless of the crystal structure. The closer that the ionic radius of the halogen atom is to the ionic radius of the chalcogen atom, the more readily the halogen atom is bonded to the chalcogen atom. The bond is formed more readily when the ionic radius of the halogen atom is equal to or less than that of the chalcogen atom than when the ionic radius of the halogen atom is greater than that of the chalcogenatom.

Accordingly, when the matrix material Mx includes a metal chalcogenide, the one or more halogen atoms preferably belong to a period identical to or higher than that of at least one chalcogen atom constituting the metal chalcogenide of the matrix material Mx. Further, when the one or more halogen atoms include two or more halogen atoms, preferably the halogen atom having the highest mass ratio among the two or more halogen atoms belongs to a period equal to or higher than that of at least one chalcogen atom constituting the metal chalcogenide. The matrix material Mx may include a metal sulfide.

It is known that the ionic radius of an atom belonging to the second period of the long form of the periodic table is significantly different from the ionic radius of an atom belonging to the third or subsequent period due to the difference in electrostatic shielding of atomic nuclei by the closed shell. Therefore, when the matrix material Mx includes a chalcogen atom of the second period (that is, oxygen), the additive Ad preferably also includes a halogen atom of the second period (that is, fluorine). When the matrix material Mx includes a chalcogen atom of the third or subsequent period, the additive Ad preferably also includes a halogen atom of the third or subsequent period.

In the high concentration distribution region Hp (including the third portion P3) of the matrix material Mx, the concentration of the additive Ad may be about the same as the density of the dangling bonds in the entire matrix material Mx. Specifically, the concentration of the additive Ad in the third portion P3 may be within a range from 10¹⁶/cm³ to 10¹⁹/cm³.

Additionally or alternatively, the additive Ad may include one or more organic compounds. In this case, the additive Ad receives an unpaired electron from a dangling bond or shares an electron with the dangling bond, thereby eliminating the dangling bond. The organic compound may be a ligand agent. A carbon chain of the organic compound is a short chain. In the disclosure, “short chain” means that the number of carbon atoms is 6 or less.

In the disclosure, “organic” means a so-called “organic compound.” Electric current, heat, light, water, and oxygen break covalent bonds and decompose organic compounds. PTL 1 discloses a quantum dot in which a fluoride-containing ligand or a fluoride anion is bonded to a surface thereof, and the fluoride-containing ligand or the fluoride anion is an organic compound. When the organic compound bonded to the surface deteriorates, a distance between the quantum dots decreases, facilitating fluorescence resonance energy transfer (FRET). Alternatively or additionally, the quantum dots are aggregated or deactivated. As a result, a luminous efficiency is reduced. Accordingly, the known technique disclosed in PTL 1 is problematic in that a durability of the light-emitting element is low.

On the other hand, “inorganic” means a so-called “inorganic compound.” Inorganic compounds are less likely to decompose than organic compounds. The matrix material Mx according to the disclosure, being made of an inorganic semiconductor, is less likely to decompose. Therefore, an aspect according to the disclosure can improve the durability of the light-emitting element. Note that the inorganic semiconductor constituting the matrix material Mx may include impurities. For example, residue and decomposition products of the organic compound, such as organic solvents, organic surfactants, organic ligand agents, and organic photoresists, may be included in the matrix material Mx. The third portion P3 of the matrix material Mx may include a carbonatom.

The inorganic semiconductor included in the matrix material Mx may be a single element composed of one group 14 element such as, for example, diamond (C), silicon (Si), or germanium (Ge). The inorganic semiconductor may be a compound of two or more group 14 elements, such as, for example, SiC or GeC. The inorganic semiconductor included in the matrix material Mx may be an inorganic compound composed of two or more elements selected from group I elements, group II elements, group III elements, group IV elements, group V elements, group VI elements, and group VII elements, or a mixed crystal thereof. The inorganic semiconductor may be, for example, a group II-VI compound such as MgO, MgS, ZnO, ZnS, ZnSe, or ZnTe, or a mixed crystal thereof. The inorganic semiconductor may be, for example, a group III-V compound such as BN, AlN, GaN, InN, AlP, GaP, InP, AlAs, GaAs, or InAs, or a mixed crystal thereof. The inorganic semiconductor may be, for example, an oxide such as Al₂O₃, Ga₂O₃, In₂O₃, and SiO₂. The inorganic semiconductor may be, for example, a nitride such as SnN. The inorganic semiconductor may be a compound composed of one or more transition metal elements and one or more group 6 elements excluding oxygen. The transition metal elements include group 3 to group 12 elements, and the group 6 elements excluding oxygen include sulfur (S), selenium (Se), and tellurium (Te). The inorganic semiconductor included in the matrix material Mx may further be a three-element compound, such as a perovskite compound or a chalcopyrite compound, or a compound composed of four or more elements.

The organic ligand agent included as the additive Ad is an organic compound capable of binding to the surface of the first quantum dot QD1. In particular, an organic compound capable of binding to a specific site such as a defect is preferable. Examples of the organic ligand agent include trioctylphosphine (TOP), trioctylphosphine oxide (TOPO), oleic acid, oleylamine, octylamine, trioctylamine, hexadecylamine, octanethiol, dodecanethiol, hexylphosphonic acid (HPA), tetradecylphosphonic acid (TDPA), and octylphosphinic acid (OPA).

The matrix material Mx may include a continuous film having an area equal to or greater than 1000 nm² in a plane direction (x-y plane direction) orthogonal to the layer thickness direction (z direction) of the light-emitting layer Em (excluding the cross section of the quantum dots QD).

### Manufacturing Method

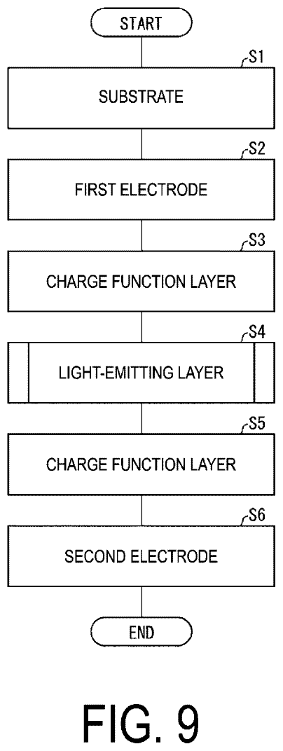

FIG. 9 is a flowchart illustrating an example of a method for manufacturing the light-emitting element illustrated in FIG. 1. As illustrated in FIG. 9, first, a substrate is prepared (step S1). The substrate may be a simple support substrate or may be an active substrate in which wiring lines and circuit elements are formed on a support substrate. Next, on the substrate, the first electrode El is formed (step S2), the charge function layer F1 is formed (step S3), and the light-emitting layer Em is formed (step S4).

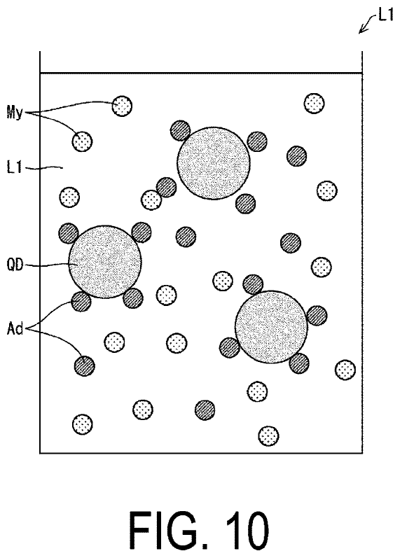

FIG. 10 is a schematic view illustrating an example of a dispersion used in the process of forming the light-emitting layer illustrated in FIG. 9. As illustrated in FIG. 10, a dispersion L1 includes a precursor My of an inorganic semiconductor, the additive Ad, the plurality of quantum dots QDs, and a solvent L2. When the inorganic semiconductor constituting the matrix material Mx is a metal sulfide, the precursor My may include, for example, at least one of a metal acetate, a metal nitrate, or a metal halide as a metal source, and thiourea, N-methylthiourea, 1,3-dimethylthiourea, N,N′-dimethylthiourea, tetramethylthiourea, or thioacetamide as a sulfur source. Alternatively, the precursor My may include a metal complex in which thiourea, N-methylthiourea, 1,3-dimethylthiourea, N,N′-dimethylthiourea, tetramethylthiourea, or thioacetamide is coordinated to a metal atom. The additive Ad acts as a ligand agent for protecting the quantum dots QD. Therefore, at least part of the additive Ad is coordinated to the surfaces of the quantum dots QD.

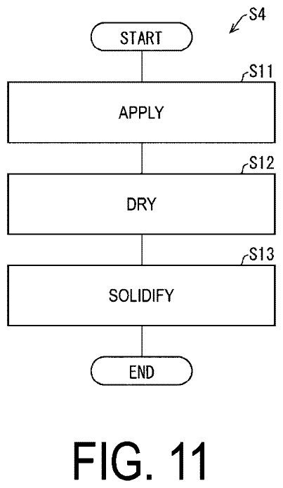

FIG. 11 is a flowchart illustrating an example of the process of forming the light-emitting layer illustrated in FIG. 9. As illustrated in FIG. 11, in the process of forming the light-emitting layer (step S4), first, the dispersion L1 is applied onto the charge function layer F1 (step S11). Next, the applied dispersion L1 is dried (step S12). In this drying, the dispersion L1 is heated at a temperature lower than a decomposition temperature of the precursor My to volatilize the solvent L2.

Then, the dried dispersion L1 is solidified (step S13). In this solidification, the dispersion L1 is heated at a high temperature equal to or higher than the decomposition temperature of the precursor My to decompose the precursor My, thereby forming an inorganic semiconductor. Any one or more of a temperature rising time, a temperature keeping time and a temperature falling time in the high temperature heating are set, ensuring slow crystal growth of the inorganic semiconductor. Accordingly, the precursor My may be decomposed by irradiating the dried dispersion L1 with visible light or near ultraviolet rays instead of or in addition to the high-temperature heating that modifies the precursor My of the inorganic semiconductor into the inorganic semiconductor, bringing a crystal growth rate at which the crystal portions CG of the inorganic semiconductor epitaxially grow from the surfaces of the quantum dots QDs to equal to or less than a thermal diffusion rate of the additive Ad.

Such slow crystal growth causes the additive Ad to separate and concentrate between the growing crystal portions CG. As a result of the separation and concentration, the high concentration distribution region Hp is formed as described above with reference to FIG. 4 to FIG. 8. Therefore, the additive Ad is likely to bond to the lattice defects in the crystal grain boundary Bd (and the vicinity thereof).

With reference again to FIG. 9, following the process of forming the light-emitting layer (step S4), the charge function layer F2 is formed (step S5), and the second electrode E2 is formed (step S6). Furthermore, to protect the light-emitting element 10 from water and oxygen, a thin film encapsulation layer covering the light-emitting element 10 may be formed.

### EXAMPLE AND COMPARATIVE EXAMPLE

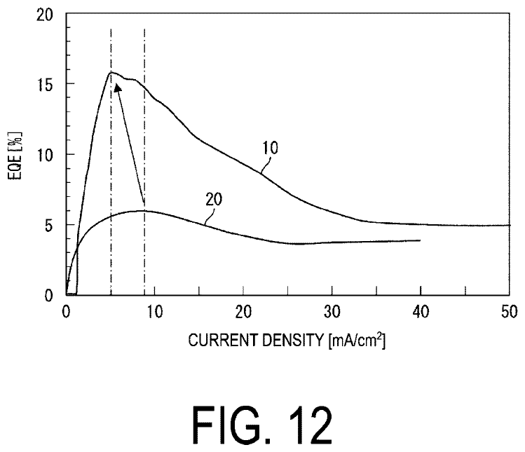

FIG. 12 is a graph showing light-emission characteristics of the light-emitting element of an example according to the disclosure and a light-emitting element according to a comparative example. In FIG. 12, the horizontal axis represents a current density applied to the light-emitting elements 10, 20, and the vertical axis represents an external quantum efficiency (EQE) of the light-emitting elements 10, 20. As illustrated in FIG. 12, the current density at which the EQE exhibits a peak in the light-emitting element 10 of the example according to the disclosure is lower than the current density at which the EQE exhibits a peak in the light-emitting element 20 of the comparative example. Further, a peak value of the EQE in the light-emitting element 10 of the example according to the disclosure is greater than a peak value of the EQE in the light-emitting element 20 of the comparative example.

The light-emitting element 10 of the example according to the disclosure was created as described above with reference to FIG. 9 to FIG. 11. Accordingly, the crystal growth of the crystal portions CG included in the matrix material Mx in the light-emitting element 10 of the example was slow. On the other hand, the light-emitting element 20 of the comparative example was created with a fast crystal growth rate in step S13, but otherwise was created in the same manner as the light-emitting element 10 of the example. Note that materials used in the light-emitting element 10 of the example and materials used in the light-emitting element 20 of the comparative example were the same.

In the light-emitting element 20 of the comparative example, presumably the additive Ad did not bond to the lattice defects generated at a high density at the crystal grain boundary Bd (and the vicinity thereof). Therefore, the dangling bonds of the lattice defects acted as non-light-emission combination centers or carrier traps, a carrier injection efficiency into the quantum dots QD was reduced, and the light-emission recombination probability was reduced. As a result, the EQE of the light-emitting element 20 exhibited a peak on the high current density side and the peak value was as low as about 5%.

On the other hand, in the light-emitting element 10 of the example, presumably the additive Ad bonded to the lattice defects generated at a high density at the crystal grain boundary Bd (and the vicinity thereof). Therefore, the lattice defects were inactivated. As a result, as compared with the light-emitting element 20 of the comparative example, the EQE of the light-emitting element 10 of the example exhibited a peak on the low current density side, and the peak value was improved to about 15%.

### Second Embodiment

Another embodiment of the disclosure will be described below. Note that members having the same functions as those of the members described in the above-described embodiment will be denoted by the same reference numerals and signs, and the description thereof will not be repeated for the sake of convenience of description.

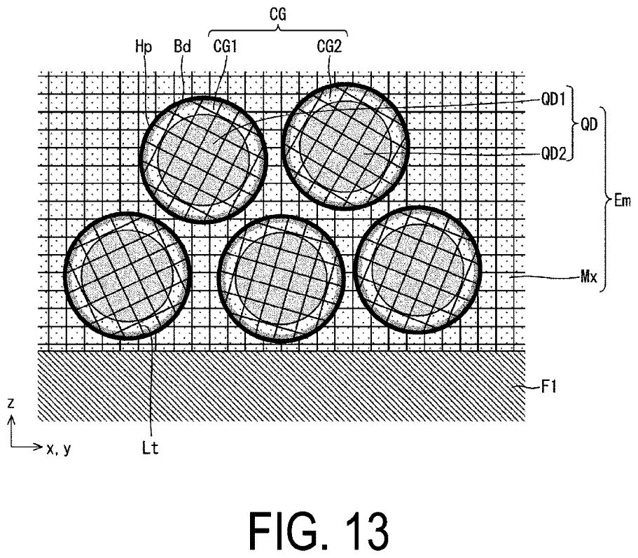

FIG. 13 is a schematic view illustrating a configuration example of the light-emitting layer of the light-emitting element according to an embodiment of the disclosure. As illustrated in FIG. 13, in the light-emitting layer Em according to the present embodiment, the first crystal portions CG1 and the second crystal portions CG2 are separated from each other to form the crystal grain boundary Bd. A portion of the matrix material Mx between the first crystal portion CG1 and the second crystal portion CG2 may be polycrystalline or amorphous, but is preferably amorphous. Other than this point, the configuration of the light-emitting element 10 according to the present embodiment is the same as the configuration of the light-emitting element 10 according to the first embodiment described above.

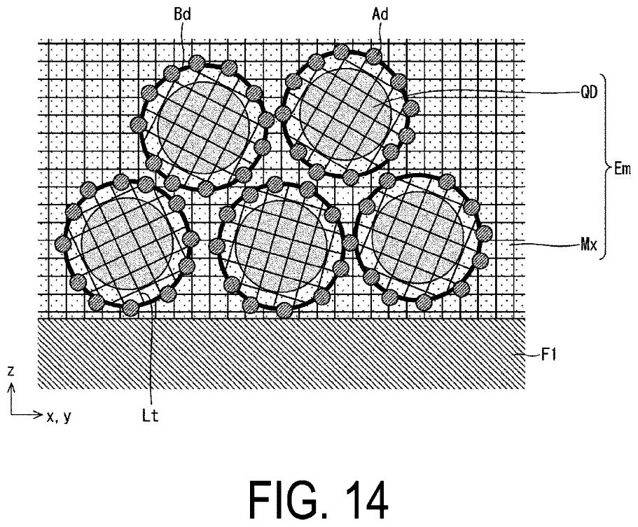

FIG. 14 is a schematic view illustrating an example of the additive being scattered in the configuration example illustrated in FIG. 13. As illustrated in FIG. 14, the additive Ad scatters in the crystal grain boundary Bd of the crystal portions CG and the vicinity thereof (that is, in the high concentration distribution region Hp). Accordingly, according to the configuration according to the present embodiment, the durability and the EQE of the light-emitting element 10 improve as in the configuration according to the first embodiment described above. Further, the EQE of the light-emitting element 10 exhibits a peak at a low current density.

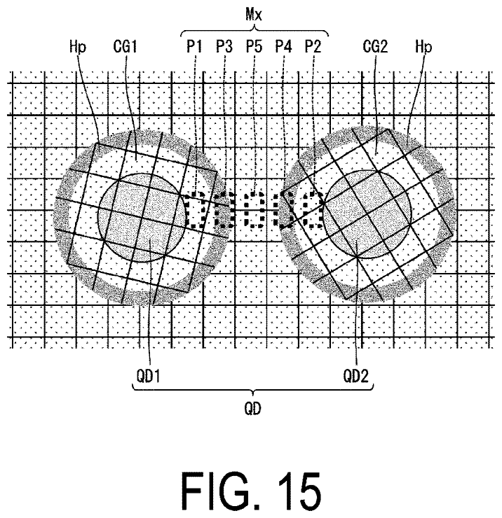

FIG. 15 is a schematic view focusing on the first quantum dot QD1 and the second quantum dot adjacent to each other and illustrated in FIG. 13 and FIG. 14. As illustrated in FIG. 15, the matrix material Mx includes the first portion P1, the second portion P2, and the third portion P3, and further includes a fourth portion P4 positioned between the second portion P2 and the third portion P3, and a fifth portion P5 positioned between the third portion P3 and the fourth portion P4. A concentration of the additive Ad in the fourth portion P4 is higher than concentrations of the additive Ad in the first portion P1 and the second portion P2. A concentration of the additive Ad in the fifth portion P5 is lower than concentrations of the additive Ad in the third portion P3 and the fourth portion P4.

In the matrix material Mx, the high concentration distribution region Hp in which the concentration of the additive Ad is higher than that of the first portion P1 and the second portion P2 and which includes the third portion P3, and the high concentration distribution region Hp in which the concentration of the additive Ad is higher than that of the first portion P1 and the second portion P2 and which includes the fourth portion P4 are separately formed. The fifth portion P5 is not included in the high concentration distribution region Hp. The first portion P1, the second portion P2, and the fifth portion P5 can include a portion in which the concentration of the additive Ad is 0. The additive Ad scatters in the third portion P3 and the fourth portion P4. The first quantum dot QD1 is surrounded by the high concentration distribution region Hp including the third portion P3, and the second quantum dot QD2 is surrounded by the high concentration distribution region Hp including the fourth portion P4.

A shape of the crystal portions CG and an arrangement of the high concentration distribution region Hp depend on a shape of the quantum dots QD and the crystal growth rate. For example, a portion of the high concentration distribution region Hp may extend along a substantially spherical surface centered on the first quantum dots QD1. For example, a portion of the high concentration distribution region Hp may have a constant distance from the surfaces of the first quantum dots QD1.

### Modified Example

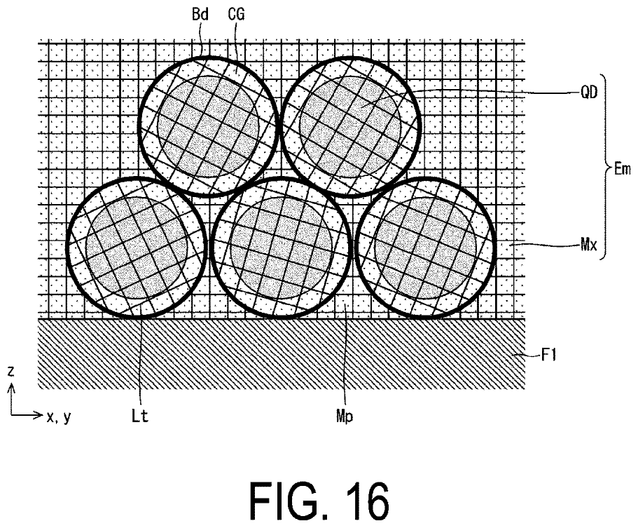

FIG. 16 is a schematic view illustrating a modified example of the light-emitting layer of the light-emitting element according to an embodiment of the disclosure. As illustrated in FIG. 16, the light-emitting layer Em of the light-emitting element 10 may have an intermediate configuration between the configuration according to the first embodiment and the configuration according to the second embodiment. For example, the crystal portions CG adjacent to each other may be partially in contact with each other. For example, several of the crystal portions CG may be separated from each other, and several other crystal portions CG adjacent to each other may be in contact with each other.

### Third Embodiment

Another embodiment of the disclosure will be described below.

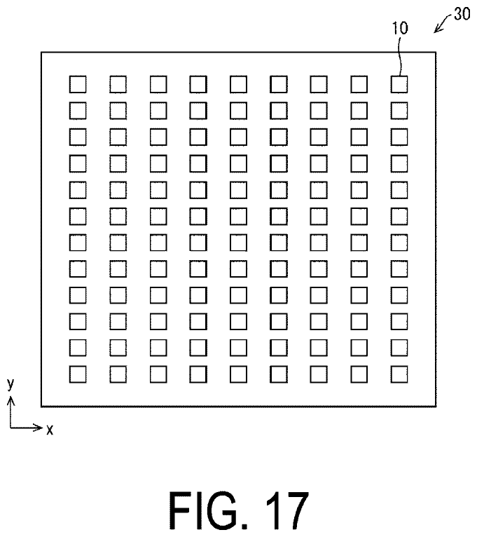

FIG. 17 is a schematic view illustrating a configuration example of a display device according to an embodiment of the disclosure. As illustrated in FIG. 17, a display device 30 according to the disclosure includes one or more light-emitting elements 10 according to the disclosure. The display device 30 includes a self-luminous display device and a display device using the light-emitting element 10 as a backlight.

The disclosure is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in each of the embodiments.

1. A light-emitting element comprising:
a light-emitting layer including a first quantum dot, a second quantum dot, and a matrix material (1) including an inorganic semiconductor and an additive, (2) filling a space between the first quantum dot and the second quantum dot, and (3) including a first portion adjacent to the first quantum dot, a second portion adjacent to the second quantum dot, and a third portion positioned between the first portion and the second portion and having a concentration of the additive higher than a concentration of each of the first portion and the second portion.

2. The light-emitting element according to claim 1,
wherein the light-emitting layer includes a quantum dot group including the first quantum dot and the second quantum dot, and
the matrix material fills a region other than the quantum dot group.

3. The light-emitting element according to claim 1,
wherein the additive includes a halogen atom.

4. The light-emitting element according to claim 3,
wherein the halogen atom is scattered throughout the third portion.

5. The light-emitting element according to claim 1,
wherein an intermediate position between the first quantum dot and the second quantum dot is present in the third portion.

6. The light-emitting element according to claim 1,
wherein a high concentration distribution region having a concentration of the additive higher than the concentration of each of the first portion and the second portion is formed in the matrix material and includes the third portion.

7. The light-emitting element according to claim 6,
wherein the first quantum dot is surrounded by the high concentration distribution region.

8. The light-emitting element according to claim 6,
wherein the high concentration distribution region has a mesh shape in a cross-sectional view of the light-emitting layer.

9. The light-emitting element according to claim 1,
wherein the matrix material includes a fourth portion positioned between the second portion and the third portion and having a concentration of the additive higher than the concentration of each of the first portion and the second portion.

10. The light-emitting element according to claim 9,
wherein the matrix material includes a fifth portion positioned between the third portion and the fourth portion and having a concentration of the additive lower than a concentration of each of the third portion and the fourth portion.

11. The light-emitting element according to claim 9,
wherein a high concentration distribution region having a concentration of the additive higher than the concentration of each of the first portion and the second portion and including the third portion and a high concentration distribution region having a concentration of the additive higher than the concentration of each of the first portion and the second portion and including the fourth portion are separately formed in the matrix material.

12. (canceled)

13. The light-emitting element according to claim 6,
wherein the matrix material includes a plurality of crystal portions, and
at least part of a crystal grain boundary of the matrix material is included in the high concentration distribution region.

14. The light-emitting element according to claim 6,
wherein part of the high concentration distribution region extends along a substantially spherical surface centered on the first quantum dot.

15. The light-emitting element according to claim 6,
wherein a distance between part of the high concentration distribution region and a surface of the first quantum dot is constant.

16. The light-emitting element according to claim 1,
wherein the first portion of the matrix material comes into contact with a core or a shell of the first quantum dot.

17-23. (canceled)

24. The light-emitting atom according to claim 3,
wherein the halogen element includes any one of fluorine, chlorine, bromine, and iodine.

25. The light-emitting element according to claim 3,
wherein the halogen atom belongs to a period identical to or higher than a period of at least one element constituting the inorganic semiconductor.

26. The light-emitting element according to claim 3,
wherein the additive includes two or more halogen-atoms, and
a halogen element having a highest mass ratio among the two or more halogen atoms belongs to a period identical to or higher than a period of at least one atom constituting the inorganic semiconductor.

27. The light-emitting element according to claim 3,
wherein the inorganic semiconductor includes a metal chalcogenide.

28-32. (canceled)

33. A method for manufacturing a light-emitting element, the method comprising:
applying a dispersion including a precursor of an inorganic semiconductor, an additive, a plurality of quantum dots, and a solvent; and
modifying the precursor of the inorganic semiconductor into the inorganic semiconductor, bringing a crystal growth rate of the inorganic semiconductor to equal to or less than a thermal diffusion rate of the additive.
